(19) United States
(12) Patent Application Publication
(10) Pub. No.: US 2006/0081466 A1
(43) Pub. Date: Apr. 20, 2006

(54) High uniformity 1-D multiple magnet magnetron source

(76) Inventors: Makoto Nagashima, Tokyo (JP); Dominik Schmidt, Stanford, CA (US)

Correspondence Address: TRAN & ASSOCIATES, 6768 MEADOW VISTA CT., SAN JOSE, CA, 95135, US

(21) Appl. No.: 10/966,383

(22) Filed: Oct. 15, 2004

(51) Int. Cl. C23C 14/32; C23C 14/00

(52) U.S. Cl. 204/298.16; 204/298.02; 204/192.1

(57) ABSTRACT

A plasma sputter reactor includes a vacuum chamber; a pedestal for supporting a substrate in said vacuum chamber; a sputtering target positioned in opposition to said pedestal; and a magnetron positioned on a side of said target opposite said sputtering target, the magnetron having magnets providing a race-track beam.

### BACKGROUND

Magnetic and MO media are widely employed in various applications, particularly in the computer industry for data/information storage and retrieval purposes. As discussed in U.S. Pat. No. 6,444,100, a magnetic medium in e.g., disk form, such as utilized in computer-related applications, comprises a non-magnetic substrate, e.g., of glass, ceramic, glass-ceramic composite, polymer, metal, or metal alloy, typically an aluminum (Al)-based alloy such as aluminum-magnesium (Al—Mg), having at least one major surface on which a layer stack comprising a plurality of thin film layers constituting the medium are sequentially deposited. Such layers may include, in sequence from the workpiece (substrate) deposition surface, a plating layer, e.g., of amorphous nickel-phosphorus (Ni—P), a polycrystalline underlayer, typically of chromium (Cr) or a Cr-based alloy such as chromium-vanadium (Cr—V), a magnetic layer, e.g., of a cobalt (Co)-based alloy, and a protective overcoat layer, typically of a carbon-based material having good mechanical (i.e., tribological) properties. A similar situation exists with MO media, wherein a layer stack is formed which comprises a reflective layer, typically of a metal or metal alloy, one or more rare-earth thermo-magnetic (RE-TM) alloy layers, one or more dielectric layers, and a protective overcoat layer, for functioning as reflective, transparent, writing, writing assist, and read-out layers, etc.

According to conventional manufacturing methodology, a majority of the above-described layers constituting magnetic and/or MO recording media are deposited by cathode sputtering, typically by means of multi-cathode and/or multi-chamber sputtering apparatus wherein a separate cathode comprising a selected target material is provided for deposition of each component layer of the stack and the sputtering conditions are optimized for the particular component layer to be deposited. Each cathode comprising a selected target material can be positioned within a separate, independent process chamber, in a respective process chamber located within a larger chamber, or in one of a plurality of separate, interconnected process chambers each dedicated for deposition of a particular layer. According to such conventional manufacturing technology, media substrates, typically in disk form, are serially transported, in linear or circular fashion, depending upon the physical configuration of the particular apparatus utilized, from one sputtering target and/or process chamber to another for sputter deposition of a selected layer thereon. In some instances, again depending upon the particular apparatus utilized, sputter deposition of the selected layer commences only when the substrate (e.g., disk) deposition surface is positioned in complete opposition to the sputtering target, e.g., after the disk has fully entered the respective process chamber or area in its transit from a preceding process chamber or area, and is at rest. Stated somewhat differently, sputter deposition commences and continues for a predetermined interval only when the substrate is not in motion, i.e., deposition occurs onto static substrates. In other instances, however, substrate transport, hence motion, between adjoining process chambers or areas is continuous, and sputter deposition of each selected target material occurs in a “pass-by” mode onto moving substrates as the latter pass by each cathode/target assembly.

Regardless of which type of sputtering apparatus is employed for forming the thin layer stacks constituting the magnetic recording medium, it is essential for obtaining high recording density, high quality media that each of the component layers be deposited in a highly pure form and with desired physical, chemical, and/or mechanical properties. Film purity depends, inter alia, upon the purity of the atmosphere in which the film is grown; hence films are grown in as low a vacuum as is practicable. However, in order to maintain the rate of sputtering of the various target materials at levels consistent with the throughput requirements of cost-effective, large-scale media manufacture, the amount of sputtering gas in the process chamber(s), typically argon (Ar), must be maintained at levels which generate and sustain plasmas containing an adequate amount of ions for providing sufficient bombardment and sputtering of the respective target material. The requirement for maintaining an adequate amount of Ar sputtering gas for sustaining the plasma at an industrially viable level, however, is antithetical to the common practice of applying a negative voltage bias to the substrates during sputter deposition thereon for achieving optimum film properties, such as, for example, the formation of carbon-based protective films containing a greater proportion of desirable sp.sup.3 bonds (as in diamond), for use as protective overcoat layers in the manufacture of disk media. Contamination of the bias-sputtered films with Ar atoms occurs because the plasmas almost always contain a large number of Ar⁺ ions, relative to the number of ions of the sputtered target species, which Ar⁺ ions are accelerated towards the negatively biased substrate surfaces and implanted in the growing films along with the sputtered target species.

Magnetos sputtering is a principal method of depositing metal onto a semiconductor integrated circuit during its fabrication in order to form electrical connections and other structures in the integrated circuit. A target is composed of the metal to be deposited, and ions in a plasma are attracted to the target at sufficient energy that target atoms are dislodged from the target, that is, sputtered. The sputtered atoms travel generally ballistically toward the wafer being sputter coated, and the metal atoms are deposited on the wafer in metallic form. Alternatively, the metal atoms react with another gas in the plasma, for example, nitrogen, to reactively deposit a metal compound on the wafer. Reactive sputtering is often used to form thin barrier and nucleation layers of titanium nitride or tantalum nitride on the sides of narrow holes.

U.S. Pat. No. 6,610,184 to Ding, et al. discloses an array of auxiliary magnets that is positioned along sidewalls of a magnetron sputter reactor on a side towards the wafer from the target. The magnetron preferably is a small, strong one having a stronger outer pole of a first magnetic polarity surrounding a weaker outer pole of a second magnetic polarity and rotates about the central axis of the chamber. The auxiliary magnets preferably have the first magnetic polarity to draw the unbalanced magnetic field component toward the wafer. The auxiliary magnets may be either permanent magnets or electromagnets.

### SUMMARY

In one aspect, a plasma sputter reactor includes a vacuum chamber; a pedestal for supporting a substrate in said vacuum chamber; a sputtering target positioned in opposition to said pedestal; and a magnetron positioned on a side of said target opposite said sputtering target, the magnetron having magnets providing a race-track beam.

In another aspect, a method for sputtering a thin film onto a substrate includes providing a plurality of deposition chambers, each having at least one target and a substrate having a film-forming surface portion and a back portion; creating a magnetic field so that the film-forming surface portion is placed in the magnetic field with the magnetic field induced normal to the substrate surface portion; back-biasing the back portion of the substrate; and sputtering material onto the film-forming surface portion.

Advantages of the system may include one or more of the following. One advantage is that multiple materials can be deposited, and that materials can be deposited on the way in and on the way out. By properly adjusting the wafer-source distance, a highly uniform deposition thickness can be achieved. The system provides sputtering techniques whose deposition rates are consistent with the throughput requirements of automated manufacturing processing. The system also produces thin films of high purity and of desired physical, chemical, and/or mechanical properties. The system sputters high purity, high quality, thin film layer stacks or laminates having optimal physical, chemical, and/or mechanical properties for use in the manufacture of single- and/or dual-sided magnetic and/or MO media, e.g., in the form of disks, which means and methodology provide rapid simple, and cost-effective formation of such media, as well as various other products and manufactures comprising at least one thin film layer.

### BRIEF DESCRIPTION OF THE FIGURES

In order that the manner in which the above-recited and other advantages and features of the invention are obtained, a more particular description of the invention briefly described above will be rendered by reference to specific embodiments thereof, which are illustrated, in the appended drawings. Understanding that these drawings depict only typical embodiments of the invention and are not therefore to be considered to be limiting of its scope, the invention will be described and explained with additional specificity and detail through the use of the accompanying drawings in which:

FIG. 1A shows one embodiment of a semiconductor processing unit.

FIG. 1B shows another embodiment of a semiconductor processing unit.

FIG. 1C shows yet another embodiment of a semiconductor processing unit.

FIG. 1D shows a further embodiment of a semiconductor processing unit.

FIG. 1E shows one embodiment of magnet arrangement.

FIG. 1F shows one embodiment of a cooling unit.

FIG. 2 shows one embodiment of an apparatus for fabricating semiconductor.

FIG. 3 is an exemplary electron distribution chart.

FIGS. 4A-4C shows one embodiment of a second apparatus for fabricating semiconductor.

FIG. 4D shows one embodiment of a second apparatus for fabricating semiconductor.

FIG. 5 shows an SEM image of an exemplary device fabricated with the system of FIG. 1.

FIG. 6 is an enlarged view of one portion of the SEM image of FIG. 5.

### DESCRIPTION

Referring now to the drawings in greater detail, there is illustrated therein structure diagrams for a semiconductor processing system and logic flow diagrams for processes a system will utilize to deposit semiconductor devices at low temperature, as will be more readily understood from a study of the diagrams.

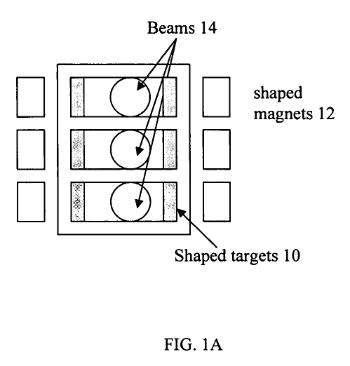

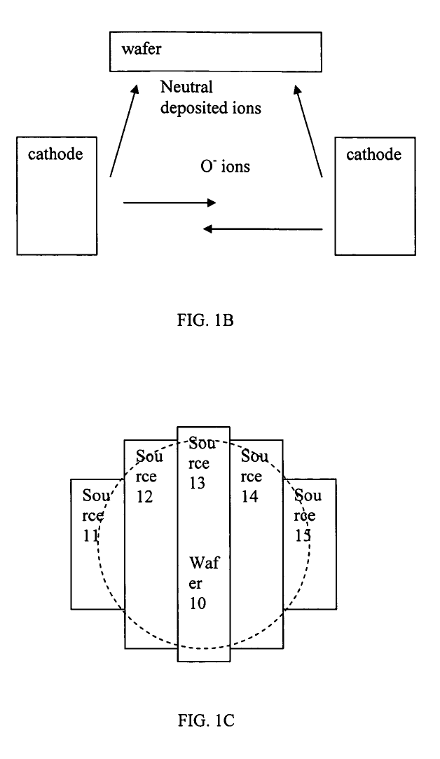

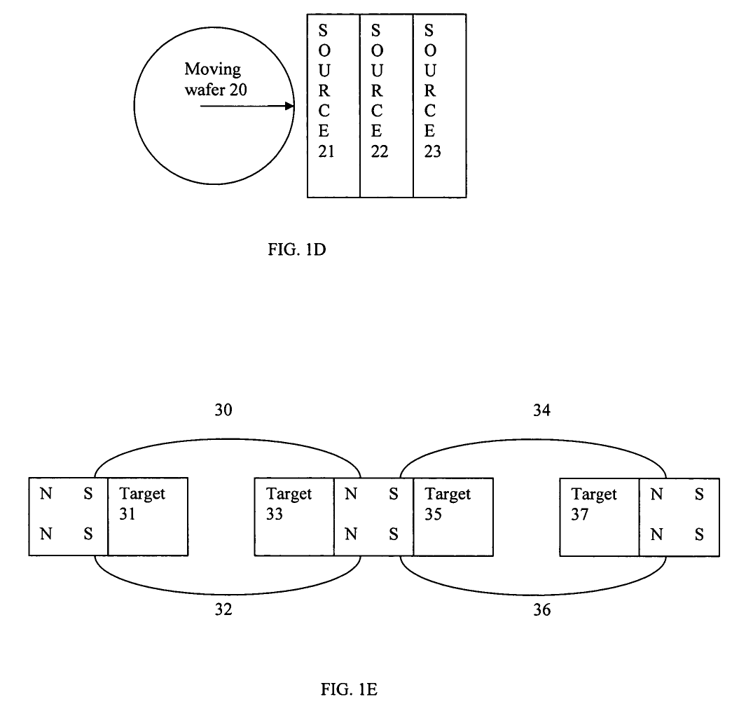

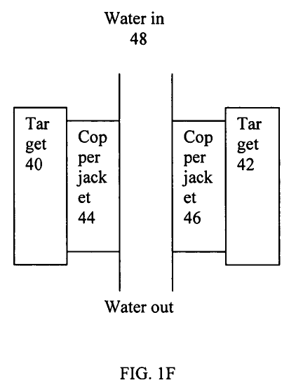

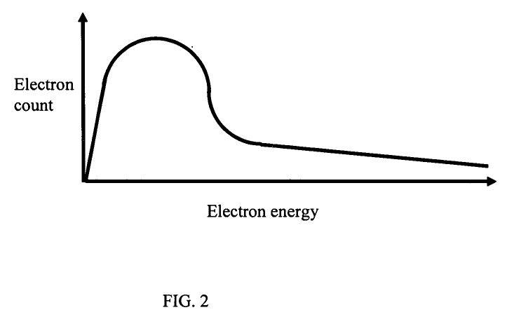

FIG. 1A shows one embodiment of a high uniformity race-track 1-D magnetron sputter reactor. The system of FIG. 1 includes one or more shaped targets 10. The shaped targets 10 can be rectangular, for example. The shaped targets 10 are positioned between shaped magnets 12. One or more oval beams 14 are generated by a magnetron 230 (FIG. 2). The beams can be oval in shape, or can be race-track in shape. As is conventional, the plasma sputter reactor of FIG. 1 includes a sputtering target, a water support pedestal which is arranged to face the consumable erosion surface of the sputtering target, and a magnetron which is arranged to face the back surface of the sputtering target. A magnetron creates a magnetic field adjacent to the erosion surface of the target to increase the plasma density and hence the sputtering rate. A working gas, such as argon, is fed into the vacuum chamber of the sputter reactor to generate plasma near the sputtering target. Particles sputtered from the sputtering target reach the wafer to form a film.

The argon working gas can be metered into the chamber from a gas supply (not shown) through a mass flow controller. A vacuum pump maintains the interior of the chamber at a low base pressure. During plasma ignition, the argon pressure is supplied in an amount producing a chamber pressure of approximately 5 milliTorr, but as will be explained later the pressure is thereafter decreased. The DC power supply negatively biases the target and causes the argon working gas to be excited into a plasma containing electrons and positive argon ions. The positive argon ions are attracted to the negatively biased target and sputter metal atoms from the target. The negative self-bias on the wafer 200 attracts the positively charged metal atoms across the sheath of the adjacent plasma, thereby coating the sides and bottoms of high aspect-ratio holes in the wafer, such as, inter-level vias.

FIG. 1B shows another exemplary sputtering system designed to provide crystallization at low temperatures. In this embodiment, incoming atoms are deposited with sufficient energy to have the surface mobility necessary to surmount the crystallization energy barrier, but not so much energy that they amorphize the pre-existing lattice. Such deposition can provide a complex metal oxide memory effect. To be effective, the system of FIG. 1B provides a way to deposit the atoms at tightly controlled energies, and prevent energetic ions and electrons from slamming into a forming layer. The arrangement requires both a magnetron magnetic field (which excites the ions in the vicinity of the targets) and a ‘barrel’ long-range magnetic field which prevents electrons from escaping and hitting the wafer.

The embodiment of FIG. 1C is scalable to large wafers. This embodiment positions a plurality of sources 11-15 over a stationary wafer 10. Alternatively, as shown in FIG. 1D, a mobile wafer 20 is positioned under one or more sources 21-23. The system of FIGS. 1C and 1D advantageously shares magnets and cooling system among the different sources.

As shown in FIG. 1E, curved magnets 30 and 32 cover targets 31 and 33, respectively. Similarly curved magnets 34 and 36 cover targets 35 and 37, respectively. FIG. 1F shows one exemplary cooling system for targets 40 and 42, each of which is in thermal conductance with a water pipe 48 through jackets 44 and 46. The jackets 44-46 can be copper or aluminum, among others.

FIG. 2 shows one embodiment of a semiconductor processing system. In this embodiment, a wafer 200 is positioned in a chamber 210. The wafer 200 is moved into the chamber 210 using a robot arm 220. The robot arm 220 places the wafer 200 on a wafer chuck 230. The wafer chuck 230 is moved by a chuck motor 240. One or more chuck heaters 250 heat the wafer 200 during processing.

Additionally, the wafer 200 is positioned between the heater 250 and a magnetron 260. The magnetron 260 serves as highly efficient sources of microwave energy. In one embodiment, microwave magnetrons employ a constant magnetic field to produce a rotating electron space charge. The space charge interacts with a plurality of microwave resonant cavities to generate microwave radiation. One electrical node 270 is provided to a back-bias generator such as the generator 26 of FIG. 1.

In the system of FIG. 2, two target plates are respectively connected and disposed onto two target holders which are fixed to both inner ends of the chamber 210 so as to make the target plates face each other. A pair of permanent magnets are accommodated in the target holders so as to create a magnetic field therebetween substantially perpendicular to the surface of the target plates. The wafer 200 is disposed closely to the magnetic field (which will define a plasma region) so as to preferably face it. The electrons emitted from the both target plates by applying the voltage are confined between the target plates because of the magnetic field to promote the ionization of the inert gas so as to form a plasma region. The positive ions of the inert gas existing in the plasma region are accelerated toward the target plates. The bombardment of the target plates by the accelerated particles of the inert gas and ions thereof causes atoms of the material forming the plates to be emitted. The wafer 200 on which the thin film is to be disposed is placed around the plasma region, so that the bombardment of these high energy particles and ions against the thin film plane is avoided because of effective confinement of the plasma region by the magnetic field. The back-bias RF power supply causes an effective DC ‘back-bias’ between the wafer 200 and the chamber 210. This bias is negative, so it repels the low-velocity electrons.

In one embodiment, the reactor of FIG. 2 includes a metal chamber that is electrically grounded. The wafer or substrate 200 to be sputter coated is supported on a pedestal electrode in opposition to a target. The electrical bias source is connected to the pedestal electrode. Preferably, the bias source is an RF bias source coupled to the pedestal electrode through an isolation capacitor. Such bias source produces a negative DC self-bias VB on the pedestal electrode. A working gas such as argon is supplied from a gas source (not shown) through a mass flow controller and thence through a gas inlet into the chamber. A vacuum pump system pumps the chamber through a pumping port.

In a multiple target embodiment, each of the targets is positioned between opposed magnets. The targets are positioned in the reactor of FIG. 2 in such a manner that two rectangular shape cathode targets face each other so as to define a plasma confining region therebetween. Magnetic fields are then generated to cover vertically the outside of the space between facing target planes by the arrangement of magnets installed in touch with the backside planes of facing targets. The facing targets can be used a cathode, and the shield plates can be used as an anode, and the cathode/anode are connected to output terminals of a direct current (DC) power supply. The vacuum vessel and the shield plates are also connected to the anode.

Under pressure, sputtering plasma is formed in the space between the facing targets while power from the power source is applied. Since magnetic fields are generated around the peripheral area extending in a direction perpendicular to the surfaces of facing targets, highly energized electrons sputtered from surfaces of the facing targets are confined in the space between facing targets to cause increased ionized gases by collision in the space. The ionization rate of the sputtering gases corresponds to the deposition rate of thin films on the substrate, then, high rate deposition is realized due to the confinement of electrons in the space between the facing targets. The substrate 200 is arranged so as to be isolated from the plasma space between the facing targets.

Film deposition on the substrate 200 is processed at a low temperature range due to a very small number of impingement of plasma from the plasma space and small amount of thermal radiation from the target planes. A typical facing target type of sputtering method has superior properties of depositing ferromagnetic materials at high rate deposition and low substrate temperature in comparison with a magnetron sputtering method. When sufficient target voltage VT is applied, plasma is excited from the argon. The chamber enclosure is grounded. The RF power supply to the chuck or pedestal causes an effective DC ‘back-bias’ between the wafer and the chamber. This bias is negative, so it repels the low-velocity electrons.

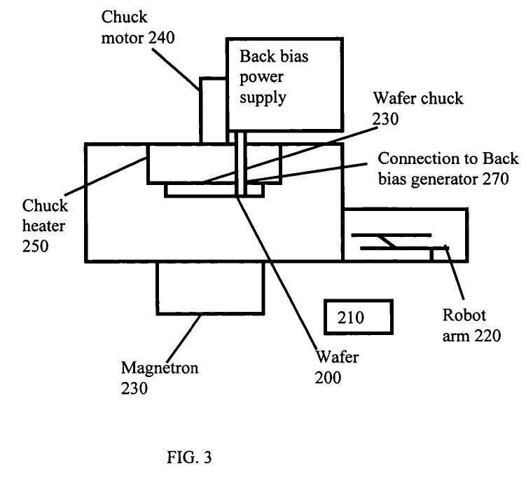

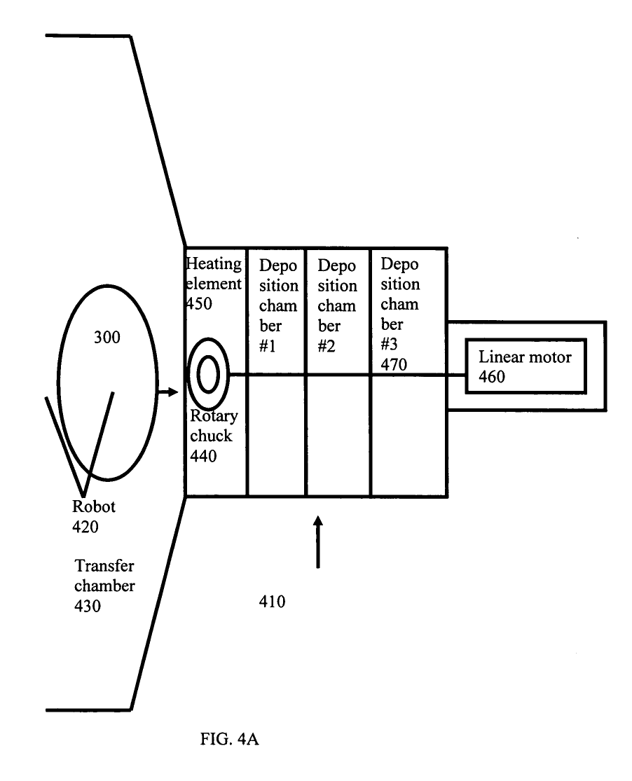

FIG. 3 illustrates an exemplary electron distribution for the apparatus of FIG. 2. The electron distribution follows a standard Maxwellian curve. Low energy electrons have two characteristics: they are numerous and they tend to have non-elastic collisions with the deposited atoms, resulting in amorphization during deposition. High-energy electrons come through the back-biased shield, but they effectively “bounce” off the atoms without significant energy transfer—these electrons do not affect the way bonds are formed. This is especially true because high energy electrons spend very little time in the vicinity of the atoms, while the low energy electrons spend more time next to the atoms and can interfere with bond formation.

The presence of the large positively biased shield affects the plasma, particularly close to the pedestal electrode 24. As a result, the DC self-bias developed on the pedestal 24, particularly by an RF bias source, may be more positive than for the conventional large grounded shield, that is, less negative since the DC self-bias is negative in typical applications. It is believed that the change in DC self-bias arises from the fact that the positively biased shield drains electrons from the plasma, thereby causing the plasma and hence the pedestal electrode to become more positive.

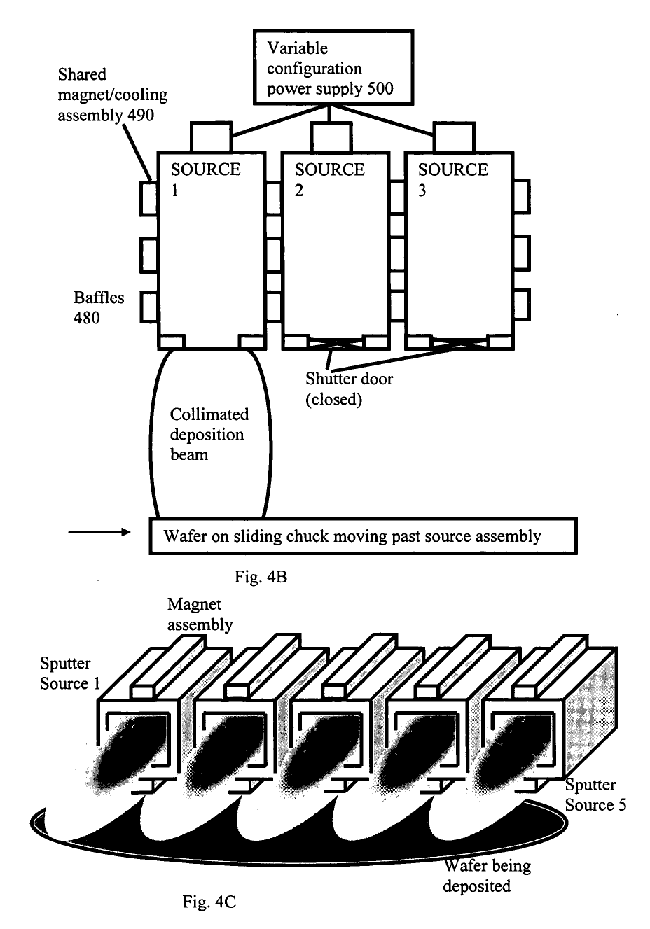

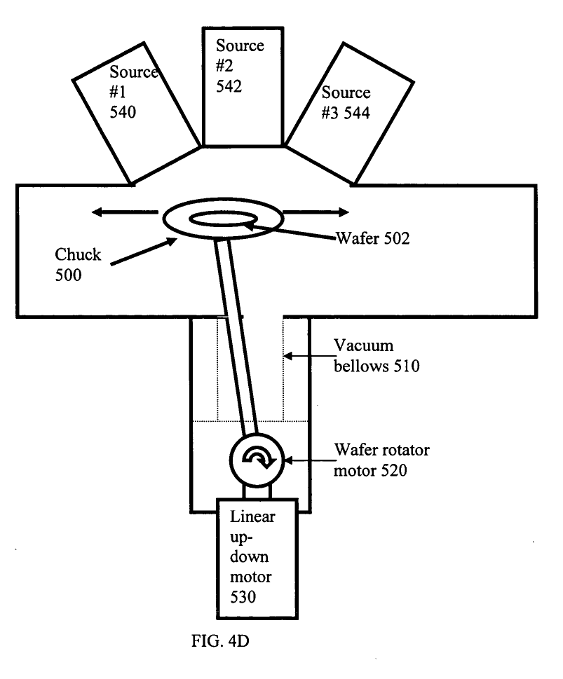

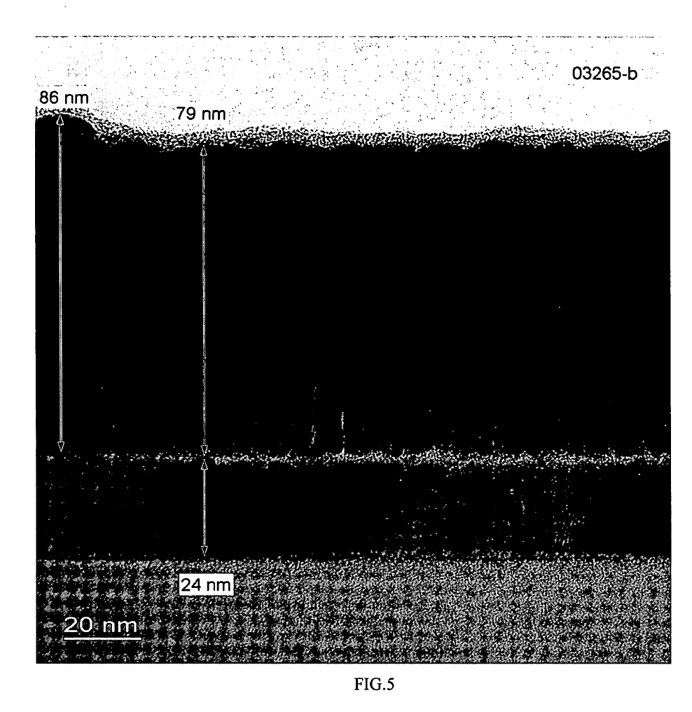

FIG. 4 shows one embodiment of a second apparatus for fabricating semiconductor. In the system of FIG. 4, multiple 1-D deposition sources are stacked in the deposition chamber. The stacking of the sources reduces the amount of wafer travel, while significantly increasing deposition uniformity. A wafer 300 is inserted into a chamber 410 using a robot arm 420 moving through a transfer chamber 430. The wafer 300 is positioned onto a rotary chuck 440 with chuck heater(s) 450 positioned above the wafer. A linear motor 460 moves the chuck through a plurality of deposition chambers 470.

FIGS. 4B-4C show in more detail the deposition chamber 470. In one embodiment, magnets are shared among chambers. The chamber 470 is a collimated design in that at the opening to the substrate, the chamber 470 has a baffle 480 to catch falling particulates and other materials. In one implementation, the baffle 480 has a straight edge. In another implementation, the baffle 480 has an angled edge to further trap particulates. Magnets 490 are positioned along the length of the chamber 470 so that they can be shared among chambers. Additionally, each chamber 470 has a pump (not shown) in addition to the system pump 34 (FIG. 1). Thus, a differential pump system is deployed. A common power supply 500 is shared among the deposition stages.

One of the deposition chambers is a facing target sputtering. The deposition chamber includes a pair of target plates placed at opposite ends of said air-tight chamber respectively so as to face each other and form a plasma region therebetween; a pair of magnets respectively disposed adjacent to said target plates such that magnet poles of different polarities face each other across said plasma region thereby to establish a magnetic field of said plasma region between said target plates; a substrate holder disposed adjacent to said plasma region, said substrate holder adapted to hold a substrate on which an alloyed thin film is to be deposited; and a back-bias power supply coupled to the substrate holder. The back-bias power supply is a DC or an AC electric power source. A robot arm is used to move the wafer. A magnetron is also in the chamber. A chuck heater can be mounted above the wafer. A rotary chuck is used to move a wafer. A linear motor can be used to move the rotary chuck and sequentially expose the wafer to the plurality of chambers. Each chamber provides a collimated deposition pattern. Each chamber includes a door that opens during each chamber's deposition and closes when the chamber is not depositing. Each door includes a baffle to catch falling particulates. The chambers share magnets. A housing pump to evacuate air from the housing. Each chamber further comprises a chamber pump. Thus, a differential pump is formed by including a housing pump to evacuate air from the housing and one chamber pump for each chamber. Each chamber comprises a facing target power supply. A variable power supply drives the target plates, where the variable power supply being adjusted for each deposition.

The system of FIGS. 4A-4B provides a plurality of one dimensional sputter deposition chambers. Each pattern can be controlled by varying the voltage to the plates, as shown in FIG. 4C. Each chamber can deposit a line of material. By moving the wafer 300 with the linear motor 460, 2-d coverage is obtained. Additionally, the system allows multi-layer deposition in the same chamber, thus minimizing contamination and increasing deposition throughput.

Turning now to FIG. 4D, a second embodiment of a fabrication apparatus is shown. In this embodiment, a chuck 500 is positioned inside a chamber. The chuck 500 supports a wafer 502. The chamber has vacuum bellows 510. The chuck 500 is driven by a wafer rotator 520 which rotates the wafer 502. The chuck 500 and the wafer 502 has a pendulum motion. The chuck 500 is also powered by a linear motor 530 to provide up/down motion. A plurality of sources 540-544 perform deposition of materials on the wafer 502.

The system of FIG. 4D gets linear motion of the wafer 502 past the three sources for uniform deposition. The system has a jointed pendulum to support the wafer and keep the wafer at a constant vertical distance from the target as the pendulum swings. The system is more stable than a system with a lateral linear arm since the chuck 500 is heavy and supports the weight of the wafer, a heater, and RF backbias circuitry and would require a very thick support arm otherwise the arm would wobble. Also, the linear arm would need to extend away from the source, resulting in large equipment. In this implementation, the arm sits below the chuck, resulting in a smaller piece of equipment and also the arm does not have to support much weight. The pendulum avoids the use of a long linear arm which wobbles and adds at least 4 feet of equipment size. The pendulum holds the wafer much more securely because the chuck is supported from underneath rather than from the side.

In one embodiment, a process for obtain variable 2D deposition coverage is as follows:
Receive desired 2D pattern from user
Move chuck into a selected deposition chamber;
Actuate linear motor and rotary chuck to in accordance with the 2D pattern
Move current wafer to next deposition chamber
Get next wafer into the current chamber and repeat process.

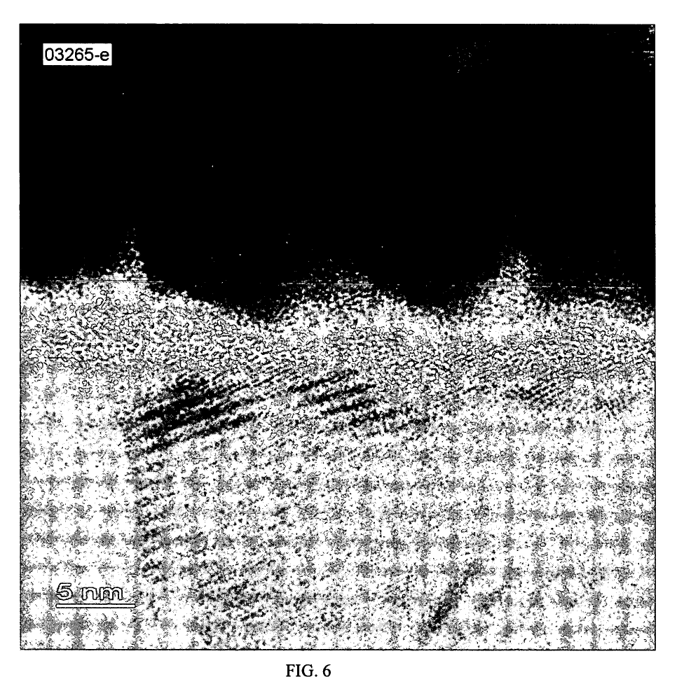

FIG. 5 shows an SEM image of an exemplary device fabricated with the system of FIG. 1, while FIG. 6 is an enlarged view of one portion of the SEM image of FIG. 5. The device of FIG. 5 was fabricated at a low temperature (below 400° C.). At the bottom of FIG. 5 is an oxide layer (20 nm thick). Above the oxide layer is a metal layer, in this case a titanium layer (24 nm thick). Above this layer is an interface layer, in this case a platinum (Pt) interface face layer (about 5 nm). Finally, a crystallite PCMO layer (79 nm thick) is formed at the top. Grains in this layer can be seen extending from the bottom toward the top with a slightly angled tilt. FIG. 6 shows a zoomed view showing the Ti metal layer, the Pt interface layer and the PCMO grain in more details.

Although one back-biased power supply is mentioned, a plurality of back-bias power supplies can be used. These power supplies can be controllable independently from each other. The electric energies supplied can be independently controlled. Therefore, the components of the thin film to be formed are easily controlled in every sputtering batch process. In addition, the composition of the thin film can be changed in the direction of the thickness of the film by using the Facing Targets Sputtering device.

It is to be understood that various terms employed in the description herein are interchangeable. Accordingly, the above description of the invention is illustrative and not limiting. Further modifications will be apparent to one of ordinary skill in the art in light of this disclosure.

The invention has been described in terms of specific examples which are illustrative only and are not to be construed as limiting. The invention may be implemented in digital electronic circuitry or in computer hardware, firmware, software, or in combinations of them.

Apparatus of the invention for controlling the fabrication equipment may be implemented in a computer program product tangibly embodied in a machine-readable storage device for execution by a computer processor; and method steps of the invention may be performed by a computer processor executing a program to perform functions of the invention by operating on input data and generating output. Suitable processors include, by way of example, both general and special purpose microprocessors. Storage devices suitable for tangibly embodying computer program instructions include all forms of non-volatile memory including, but not limited to: semiconductor memory devices such as EPROM, EEPROM, and flash devices; magnetic disks (fixed, floppy, and removable); other magnetic media such as tape; optical media such as CD-ROM disks; and magneto-optic devices. Any of the foregoing may be supplemented by, or incorporated in, specially-designed application-specific integrated circuits (ASICs) or suitably programmed field programmable gate arrays (FPGAs).

While the preferred forms of the invention have been shown in the drawings and described herein, the invention should not be construed as limited to the specific forms shown and described since variations of the preferred forms will be apparent to those skilled in the art. Thus the scope of the invention is defined by the following claims and their equivalents.

What is claimed is:

1. A plasma sputter reactor, comprising:
a vacuum chamber;
a pedestal for supporting a substrate in said vacuum chamber;
a sputtering target positioned in opposition to said pedestal; and
a magnetron positioned on a side of said target opposite said sputtering target, the magnetron having magnets providing a race-track beam.

2. The system of claim 1, comprising:
an air-tight housing in which an inert gas is admittable and exhaustible; and
a plurality of deposition chambers positioned within the system.

3. The system of claim 2, wherein one of the deposition chamber further comprises:
a pair of target plates placed at opposite ends of said air-tight chamber respectively so as to face each other and form a plasma region therebetween;
a pair of magnets respectively disposed adjacent to said target plates such that magnet poles of different polarities face each other across said plasma region thereby to establish a magnetic field of said plasma region between said target plates;
a substrate holder disposed adjacent to said plasma region, said substrate holder adapted to hold a substrate on which an alloyed thin film is to be deposited; and
a back-bias power supply coupled to the substrate holder.

4. A facing targets sputtering device according to claim 3, wherein the back-bias power supply is a DC or an AC electric power source.

5. A facing targets sputtering device according to claim 1, further comprising a robot arm to move the wafer.

6. A facing targets sputtering device according to claim 1, further comprising a magnetron coupled to the chamber.

7. A facing targets sputtering device according to claim 1, further comprising a chuck heater mounted above the wafer.

8. The apparatus of claim 1, further comprising a rotary chuck to move a wafer.

9. The apparatus of claim 1, further comprising a linear motor to move the rotary chuck and sequentially expose the wafer to a plurality of chambers.

10. The apparatus of claim 1, wherein each chamber provides a collimated deposition pattern.

11. The apparatus of claim 1, wherein each chamber further comprises a door that opens during each chamber's deposition and closes when the chamber is not depositing.

12. The apparatus of claim 11, wherein each door comprises a baffle to catch falling particulates.

13. The apparatus of claim 1, wherein the chambers share magnets.

14. The apparatus of claim 1, further comprising a housing pump to evacuate air from the housing.

15. The apparatus of claim 1, wherein each chamber further comprises a chamber pump.

16. The apparatus of claim 1, further comprising chuck supported from underneath the wafer.

17. The apparatus of claim 1, further comprising a jointed pendulum to support the wafer and keep the wafer at a constant vertical distance from the target as the pendulum swings.

18. A method for sputtering a thin film onto a substrate, comprising:
providing a plurality of deposition chambers, each having at least one target and a substrate having a film-forming surface portion and a back portion;
creating a magnetic field so that the film-forming surface portion is placed in the magnetic field with the magnetic field induced normal to the substrate surface portion
back-biasing the back portion of the substrate; and
sputtering material onto the film-forming surface portion.

19. A method as in claim 18, further comprising swinging the wafer using a pendulum.

20. A method as in claim 18, further comprising supporting a chuck from underneath the wafer.
